(19) United States
(12) Patent Application Publication
(10) Pub. No.: US 2016/0307879 A1
(43) Pub. Date: Oct. 20, 2016

(54) Light Emitting Module

(71) Applicant: Everlight Electronics Co., Ltd., New Taipei (TW)

(72) Inventors: Ya-Huei Lien, New Taipei (TW); Chung-kai Chang, New Taipei (TW)

(21) Appl. No.: 14/992,863

(22) Filed: Jan. 11, 2016

(30) Foreign Application Priority Data
Apr. 20, 2015 (TW) 104112567

(51) Int. Cl. H01L 25/075; H01L 33/56; H01L 33/54; H01L 27/15

(52) U.S. Cl. CPC H01L 25/0753; H01L 27/156; H01L 33/56; H01L 33/54

(57) ABSTRACT

A light emitting module including an electrode substrate and a plurality of light emitting diodes is provided. The electrode substrate includes a carrying surface, and further includes a first joint portion and a second joint portion that are located at opposite ends of the electrode substrate respectively. The first joint portion includes a first through hole or a first notch. The plurality of light emitting diodes is disposed on the carrying surface of the electrode substrate, wherein the plurality of light emitting diodes is arranged along a long side direction of the electrode substrate, and is electrically coupled to the electrode substrate.

### CROSS-REFERENCES TO RELATED APPLICATIONS

This application claims priority to Taiwan Patent Application No. 104112567, filed on Apr. 20, 2015, which is incorporated by reference in its entirety.

### TECHNICAL FIELD

The present invention relates to a light emitting module.

### DESCRIPTIONS OF RELATED ART

Owing to rapid development of the semiconductor technologies, currently light-emitting diodes (LEDs) can provide a high luminance output and be used in various light mixing applications. The LEDs operate in the following way: by applying a current to a compound semiconductor, electrons and holes are recombined so that energy is released in the form of light. Because the LEDs emit light not through heating or discharging, the LEDs have a long lifetime of more than one hundred thousands of hours. Moreover, as compared with the conventional incandescent light sources, the LEDs further have such advantages as power saving, a small volume, and a short response time, so they have been widely used in displays and lighting applications.

As the whole lighting market evolves from the conventional lighting towards LED lighting, LED filaments in the form of conventional incandescent lamps to which people are familiar and having the advantages of LEDs have received much attention in recent years. In order for the LED filaments to present good light emission uniformity at various angles, most of the LED filaments use nonconductive transparent substrates to carry the LEDs and have the LEDs connected to electrodes through spot soldering and external metal leads. However, this makes the manufacturing process complex, and the spot soldering presents a risk of loose of the soldered point, which leads to a poor reliability.

### SUMMARY

The present invention provides a light emitting module which makes the substrate connecting process simple and the connection reliable.

The present invention provides a light emitting mode which presents good light emission uniformity.

An embodiment of the present invention discloses a light emitting module, which comprises an electrode substrate and a plurality of light emitting diodes (LEDs). The electrode substrate comprises a carrying surface, and further comprises a first joint portion and a second joint portion that are located at two opposite ends of the electrode substrate respectively, and the first joint portion comprises a first through hole or a first notch. The plurality of LEDs is disposed on the carrying surface of the electrode substrate, wherein the LEDs are arranged along a long side direction of the electrode substrate and are electrically coupled to the electrode substrate.

In an embodiment of the present invention, the electrode substrate comprises a first electrode board, a second electrode board and an electrically-insulative connecting portion configured to connect the first electrode board and the second electrode board. The LEDs are disposed on the second electrode board. Each of the LEDs has one end thereof electrically connected to the first electrode board and another end thereof electrically connected to the second electrode board.

In an embodiment of the present invention, the light emitting module further comprises a fluorescent encapsulant that covers the electrode substrate and the LEDs.

In an embodiment of the present invention, the LEDs comprise one or more high-voltage (HV) LEDs, one or more direct-current (DC) LEDs, one or more alternating-current (AC) LEDs, or a combination thereof.

In an embodiment of the present invention, the electrode substrate further comprises apertures for light transmission.

In an embodiment of the present invention, the fluorescent encapsulant covers the electrode substrate and the LEDs in an encapsulant form in a surface direction orthogonal to the long side direction of the electrode substrate. The fluorescent encapsulant extends to cover the electrode substrate and the LEDs in the encapsulant form along the long side direction of the electrode substrate and encapsulates the LEDs therein.

In an embodiment of the present invention, the fluorescent encapsulant has a first surface and a second surface that are opposite to each other. The LEDs and the electrode substrate are located between the first surface and the second surface. The carrying surface of the electrode substrate faces towards the first surface. A maximum distance between the carrying surface and the first surface in a direction perpendicular to the carrying surface is an upper encapsulant thickness. A maximum distance between a back surface of the electrode substrate that is opposite to the carrying surface and the second surface in the direction perpendicular to the carrying surface is a lower encapsulant thickness. The upper encapsulant thickness is greater than the lower encapsulant thickness.

In an embodiment of the present invention, the first surface of the fluorescent encapsulant comprises a curved convex surface and the second surface of the fluorescent encapsulant comprises a curved convex surface.

In an embodiment of the present invention, the first surface of the fluorescent encapsulant comprises a curved convex surface and the second surface of the fluorescent encapsulant comprises a planar surface.

In an embodiment of the present invention, the second joint portion of the electrode substrate comprises a second through hole or a second notch.

An embodiment of the present invention discloses a light emitting module comprising a carrying surface, which comprises an electrode substrate, a plurality of LEDs and a fluorescent encapsulant. The LEDs are disposed on the carrying surface of the electrode substrate, wherein the LEDs are arranged along a long side direction of the electrode substrate and electrically coupled to the electrode substrate. The fluorescent encapsulant covers the electrode substrate and the LEDs, and has a first surface and a second surface that are opposite to each other. The LEDs and the electrode substrate are located between the first surface and the second surface. The carrying surface faces towards the first surface. A maximum distance between the carrying surface and the first surface in a direction perpendicular to the carrying surface is an upper encapsulant thickness. A maximum distance between a back surface of the electrode substrate that is opposite to the carrying surface and the second surface in the direction perpendicular to the carrying surface is a lower encapsulant thickness. The upper encapsulant thickness is greater than the lower encapsulant thickness.

As can be known from the above descriptions, in the light emitting module according to one of the embodiments of the present invention, the electrode substrate comprises a first joint portion and an opposite second joint portion which are located at two opposite ends of the electrode substrate respectively. The first joint portion comprises a first through hole or a first notch. By applying present invention, the substrate connecting process is made simple and reliable because metal wires may be connected not through spot soldering which presents a risk of loose of the soldered point and thus leads to a poor reliability. In the light emitting module according to another embodiment of the present invention, the electrode substrate and the LEDs are covered by the fluorescent encapsulant and the upper encapsulant thickness is greater than the lower encapsulant thickness, so the light emitting module presents good light emission uniformity.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a schematic top view of a light emitting module according to an embodiment of the present invention.

FIG. 1B is a schematic top view of a light emitting module according to another embodiment of the present invention.

FIG. 1C is a schematic cross-sectional view of the light emitting module shown in FIG. 1A.

FIG. 2A is a graph of illuminance versus positions (angles) of the light emitting module shown in FIG. 1A.

FIG. 2B is a graph of color temperature versus positions (angles) of the light emitting module shown in FIG. 1A.

FIG. 3A is a schematic cross-sectional view of a light emitting module according to a further embodiment of the present invention.

FIG. 3B is a schematic cross-sectional view of a light emitting module according to yet a further embodiment of the present invention.

FIG. 3C is a graph of illuminance versus positions (angles) of the light emitting module shown in FIG. 3A.

FIG. 3D is a graph of color temperature versus positions (angles) of the light emitting module shown in FIG. 3A.

FIG. 4 is a schematic cross-sectional view of a light emitting module according to yet another embodiment of the present invention.

### DESCRIPTION OF THE PREFERRED EMBODIMENT

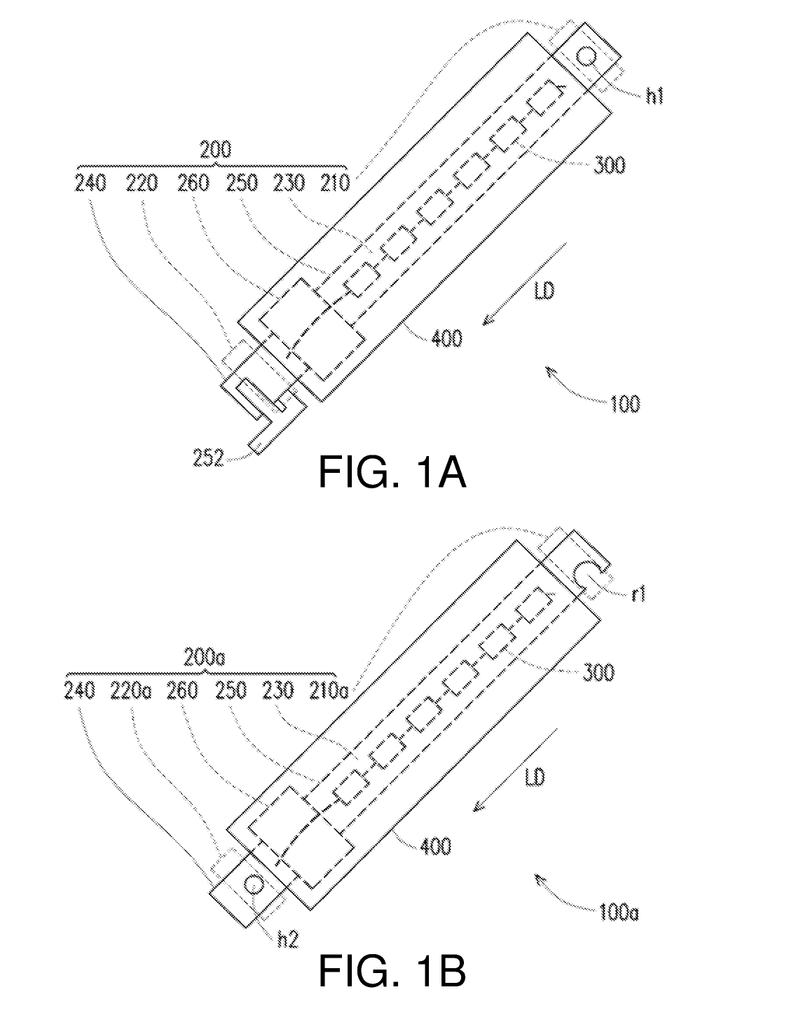

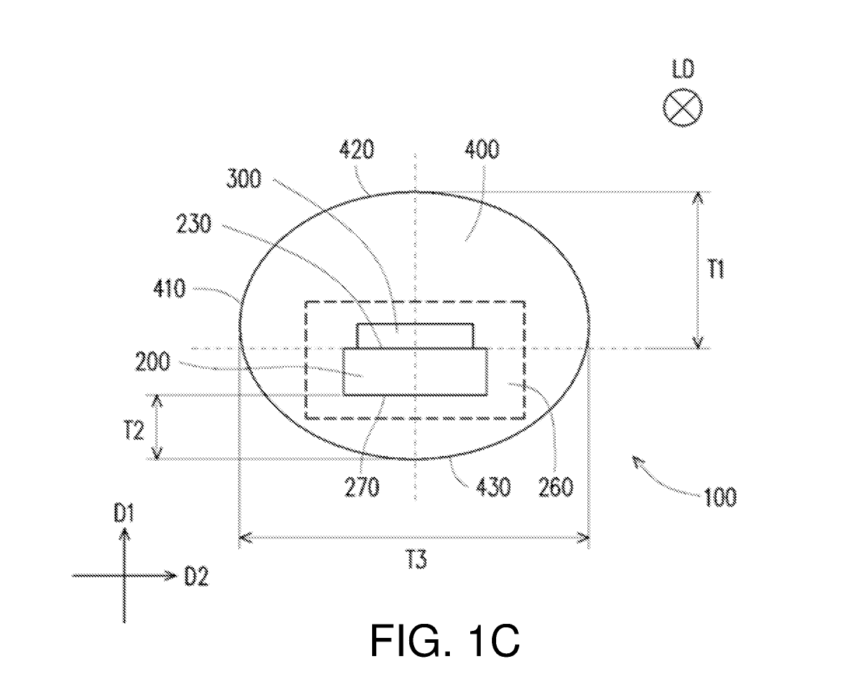

FIG. 1A is a schematic top view of a light emitting module according to an embodiment of the present invention. Referring to FIG. 1A, the light emitting module 100 in this embodiment comprises an electrode substrate 200 and a plurality of light-emitting diodes (LEDs) 300. The LEDs 300 can be, for example, HV-LED, DC-LED, OLED, III-V compound LED, LD, photonic Crystal LED, Hybrid LED, Nanorod LED, HP LED, or AC-LED. The LED die can be electrically connected via wire bonding, tape automated bonding or flip chip bonding. The LED die can be packaged as SMD type, DIP type, high power type, piranha type or without any package. The present invention is not limited thereto. The electrode substrate 200 comprises a first joint portion 210 and an opposite second joint portion 220 which are located at two opposite ends of the electrode substrate 200 respectively. The electrode substrate 200 is an electrically conductive substrate. The electrode substrate 200 is, for example, a metal electrode substrate, or a circuit substrate having conductive wirings such as a printed circuit board (PCB), a metal core printed circuit board (MCPCB) or a multi-layer printed circuit board (MPCB), but the present invention is not limited thereto. Additionally, the LEDs 300 are disposed on a carrying surface 230 of the electrode substrate 200. The LEDs 300 are arranged along a long side direction LD of the electrode substrate 200 in series with or in parallel to each other, and are electrically coupled to the electrode substrate 200. In particular, if the electrode substrate 200 is, for example but not limited to, a metal electrode substrate, the electrode substrate 200 may further comprise a first electrode board 240, a second electrode board 250 and an electrically insulative connecting portion 260 for connecting the first electrode board 240 and the second electrode board 250. The LEDs 300 are disposed on the second electrode board 250, and the second electrode board 250 can comprise apertures (not shown) for the light to pass through the electrode board. Each of the LEDs 300 has one end electrically connected to the first electrode board 240 and the other end electrically connected to the second electrode board 250. In this embodiment, because the first electrode board 240 and the second electrode board 250 are separated from each other by the insulative connecting portion 260, the anode and the cathode of each of the LEDs 300 will not be short-circuited. Additionally, the insulative connecting portion 260 may be a plastic casing having an insulative property or be some other member adapted to join a plurality of conductive objects together but insulate these conductive objects from each other, but the present invention is not limited thereto. In other embodiments, if the electrode substrate 200 is, for example but not limited to, a circuit substrate having conductive wirings, the electrode substrate 200 may further comprise a plurality of circuit wirings so that the LEDs 300 are disposed on the electrode substrate 200, e.g., in series with more than one HV LEDs and more than one LV LEDs or in parallel to each other.

In particular, the electrode substrate 200 of the light emitting module 100 may be of a strip type, and a shape of the electrode substrate 200 may be similar to that of a filament structure of a conventional incandescent lamp so that the light emitting module 100 may be installed inside a casing of the conventional incandescent lamp to simulate an incandescent lamp filament. Additionally, the electrode substrate 200 of the light emitting module 100 may also be of other forms (e.g., a spiral form, a U-shaped form or a W-shaped form), and the LEDs 300 may also be arranged in different ways on the electrode substrate 200 along the long side direction LD, and the present invention is not limited thereto.

Referring still to FIG. 1A, in this embodiment, the first joint portion 210 of the electrode substrate 200 comprises a first through hole h1 adapted to allow a wire to pass therethrough or to be supported therein. The second joint portion 220 may further be fixed and connected by using wires of a clamp 252 to clamp the second joint portion 220, but the present invention is not limited thereto. In other words, the second joint portion 220 may also comprise a through hole or a notch structure. The clamp 252 may be a clamping member made of a metal material, or may be some other clamping member having a conductive property. In particular, the light emitting module 100 of this embodiment has the LEDs 300 supported on the electrode substrate 200 but not on a nonconductive transparent substrate. The LEDs 300 can be, for example, HV-LED, DC-LED, OLED, III-V compound LED, LD, photonic Crystal LED, Hybrid LED, Nanorod LED, HP LED, or AC-LED. The LED die can be electrically connected via wire bonding, tape automated bonding or flip chip bonding. The LED die can be packaged as SMD type, DIP type, high power type, piranha type or without any package. The present invention is not limited thereto. When one end of the LEDs 300 connected in series or in parallel are to be connected with a metal wire, it is unnecessary to spot solder the one end of the LEDs to the external metal wire via a metal electrode lead. Instead, the LEDs 300 can be electrically connected to the second electrode board 250 directly and then, via the second electrode board 250, connected to the metal wire passing through or coiled around and tied to the first through hole h1. Additionally, the second electrode board 250 can further comprise apertures (not shown) for the light to pass through the electrode board. Accordingly, the light emitting module 100 of this embodiment has an effect of more reliable connection and can prevent the risk of loose of the soldered point. However, the present invention is not limited thereto, and in other words, spot soldering may be further performed after the metal wire passes through or is coiled around and tied to the first through hole h1. Additionally, as compared with a light emitting module that uses a nonconductive transparent substrate, the light emitting module 100 of this embodiment can be electrically connected to an external metal wire without the need of additional metal electrode leads, and this makes the manufacturing process of the light emitting module 100 simpler. The position and the shape of the first through hole h1 of the embodiment of the present invention are not limited to what depicted in FIG. 1A, and the first through hole h1 may also be disposed in the second joint portion 220.

FIG. 1B is a schematic top view of a light emitting module according to another embodiment of the present invention. Referring to FIG. 1B, the light emitting module 100a in this embodiment is similar to the light emitting module 100 shown in FIG. 1A; and for similar members and related functions, reference may be made to descriptions of the light emitting module 100 and no further description will be made herein. The light emitting module 100a differs from the light emitting module 100 mainly in that, the electrode substrate 200a of the light emitting module 100a comprises a first joint portion 210a and a second joint portion 220a which are located at two opposite ends of the electrode substrate 200a respectively. The first joint portion 210a comprises a first notch r1 and the second joint portion 220a comprises a second through hole h2; however, the present invention is not limited thereto, and in other embodiments, the first notch r1 and the second through hole h2 may be swapped in position, or the two opposite ends of the electrode substrate 200a both have a first notch r1 or both have a second through hole h2. In this embodiment, the function of the first notch r1 is similar to that of the first through hole h1, and the first notch r1 is adapted to allow a wire to pass therethrough or to be supported therein. For example, the metal wire is fixed to the first notch r1 by passing therethrough or being coiled around and tied to the first notch r1 so that the electrode substrate 200a is reliably connected to the metal wire. In this way, the LEDs 300 can be electrically connected to the second electrode board 250 directly and then, via the second electrode board 250, is connected to the metal wire passing through or coiled around and tied to the first notch r1. Additionally, spot soldering may be further performed after the metal wire passes through or coiled around and tied to the first notch r1.

In particular, the first notch r1 may be located at any position on the second joint portion 220a of the first electrode board 240 or the first joint portion 210a of the second electrode board 250, and the position and the shape of the first notch r1 in the embodiment of the present invention are not limited to what shown in FIG. 1B.

Additionally, the second electrode board 250 can further comprise apertures (not shown) for the light to pass through the electrode board.

Besides, in this embodiment, the second joint portion 220a comprises a second through hole h2. The second through hole h2 is similar to the first through hole h1 in function, and is also adapted to allow a wire to pass therethrough or to be supported therein so that the light emitting module 100a can be connected to an external metal wire directly via the second through hole h2 of the first electrode board 240 by passing the metal wire through (or coiling the metal wire around and tying the metal wire to) the second through hole h2. In particular, the second joint portion 220a may also comprise a second notch similar to the first notch r1. For the related function of the second notch, reference may be made to the description of the first notch r1 and no further description will be made herein. The numbers of the first through hole h1, the second through hole h2 or the first notch r1 in the embodiment of the present invention are not limited to what shown in FIG. 1A and FIG. 1B, and in other embodiments, a plurality of through holes or notches, or at least one through hole in combination with at least one notch may be disposed on the first joint portion 210 (210a), on the second joint portion 220 (220a), or on the first and the second joint portions of the light emitting module 100 (100a).

FIG. 1C is a schematic cross-sectional view of the light emitting module shown in FIG. 1A. Referring to FIG. 1C together with FIG. 1A, the light emitting module 100 in this embodiment further comprises a fluorescent encapsulant 400 covering the electrode substrate 200 and the LEDs 300. The fluorescent encapsulant 400 covers the electrode substrate 200 and the LEDs 300 in an encapsulant form 410 in a surface direction orthogonal to the long side direction LD of the electrode substrate 200, and the fluorescent encapsulant 400 extends to cover the electrode substrate 200 and the LEDs 300 in the encapsulant form 410 along the long side direction LD of the electrode substrate 200 and encapsulates the LEDs 300 into the fluorescent encapsulant 400. In this embodiment, the fluorescent encapsulant 400 further covers the insulative connecting portion 260 in the encapsulant form 410 so that both the LEDs 300 and the insulative connecting portion 260 are located within the fluorescent encapsulant 400.

In particular, the fluorescent encapsulant 400 is adapted to absorb light of a first wavelength, convert the light of the first wavelength into light of a second wavelength and emit the light of the second wavelength, where the second wavelength is greater than the first wavelength. In this embodiment, the fluorescent encapsulant 400 may be an adhesive containing phosphor, e.g., an adhesive containing yttrium aluminum garnet phosphor (YAG phosphor). The fluorescent encapsulant 400 is adapted to convert a part (e.g., blue light) of the light having the first wavelength into light of the greater second wavelength (i.e., yellow light). However, the present invention is not limited thereto, and the fluorescent encapsulant 400 may also be an adhesive containing other species of phosphors and be adapted to convert light bands corresponding to the phosphors contained therein; and also, the conversion is not limited to conversion from a shorter wavelength into a greater (longer) wavelength, but may also be a conversion from a longer wavelength into a shorter wavelength. The LEDs 300 may be LEDs of different colors, e.g., red, green or other colors of LEDs, and the light emitting module 100 may also comprise LEDs 300 of different colors. Additionally, the fluorescent encapsulant 400 covering the LEDs 300 acts not only as a material for converting the wavelength of the light emitted from the LEDs 300, but also as a material for protecting the LEDs 300 and wirings thereof. In particular, the fluorescent encapsulant 400 covers not only the LEDs 300, but also wirings for connecting the LEDs 300 in series, wirings for connecting the LEDs 300 to the first electrode board 240 and wirings for connecting the LEDs 300 to the second electrode board 250. As being protected by the fluorescent encapsulant 400, the LEDs 300 and the aforesaid wirings are less liable to damage. Referring still to FIG. 1C, the fluorescent encapsulant 400 in this embodiment has a first surface 420 and a second surface 430 opposite to each other. The first surface 420 is a curved convex surface and the second surface 420 is a curved convex surface, and the LEDs 300 and the electrode substrate 200 are located between the first surface 420 and the second surface 430. The carrying surface 230 of the electrode substrate 200 faces towards the first surface 420. Additionally, a maximum distance between the carrying surface 230 and the first surface 420 in a direction D1 perpendicular to the carrying surface 230 is an upper encapsulant thickness T1. A maximum distance between a back surface 270 of the electrode substrate 200, that is opposite to the carrying surface 230, and the second surface 430 in the direction D1 perpendicular to the carrying surface 230 is a lower encapsulant thickness T2. Furthermore, a maximum distance of the fluorescent encapsulant 400 in a direction orthogonal (or perpendicular) to the direction D1 is a side encapsulant thickness T3.

In this embodiment, because the fluorescent encapsulant 400 covers the electrode substrate 200 and the LEDs 300 and encapsulates the LEDs 300 into the fluorescent encapsulant 400, at least a part of the light emitted by the LEDs 300 in the direction D1 can be reflected or scattered by the phosphor in the fluorescent encapsulant 400 to exit from the first surface 420 and/or the second surface 430 of the fluorescent encapsulant 400. More specifically, because the LEDs 300 are located within the fluorescent encapsulant 400 in the light emitting module 100 of this embodiment, a part of the light emitted by the LEDs 300 in the direction D1 can still exit from the second surface 430 of the fluorescent encapsulant 400 through being reflected and/or scattered by the phosphor even though the LEDs 300 are carried by the opaque electrode substrate 200 in the light emitting module 100 of this embodiment. Therefore, the light emitting module 100 of this embodiment can provide an effect of emitting light in various directions (at various angles) from the first surface 420 and the second surface 430, i.e., can emit light within a large range.

Additionally, the electrode substrate 200 can further comprise apertures (not shown) for the light to pass through the electrode board.

In this embodiment, the upper encapsulant thickness T1 of the fluorescent encapsulant 400 is greater than the lower encapsulant thickness T2. In particular, a ratio of the lower encapsulant thickness T2 to the upper encapsulant thickness T1 may range between 0.22 and 0.43 in this embodiment. Preferably, the ratio of the lower encapsulant thickness to the upper encapsulant thickness ranges between 0.25 and 0.30. For example, the upper encapsulant thickness T1 of the light emitting module 100 may be 1.56 millimeter (mm), the lower encapsulant thickness T2 may be 0.45 mm, and the side encapsulant thickness T3 may be 1.86 mm. Because the LEDs 300 are carried by the opaque electrode substrate 200 in the light emitting module 100 of this embodiment, the light exiting in various directions (at various angles) from the second surface 430 must be obtained by using the phosphor in the fluorescent encapsulant 400 to reflect and/or scatter a part of the light having the first wavelength (e.g., the blue light wavelength) emitted by the LEDs 300 in the direction D1. Therefore, as compared with the light exiting from the first surface 420, the light exiting from the second surface 430 is more likely to travel a longer distance and, thus, is more likely to excite the phosphor in the fluorescent encapsulant 400 so as to be converted into light of a second wavelength (e.g., the yellow light wavelength), which makes the color temperature of the light exiting from the second surface 430 higher. In this embodiment, because the upper encapsulant thickness T1 of fluorescent encapsulant 400 is greater than the lower encapsulant thickness T2 in the light emitting module 100 of this embodiment, the path length of the light exiting from the first surface 420 and the path length of the light exiting from the second surface 430 become close to each other and, therefore, the color temperatures thereof become close to each other. In this way, the light emitting module 100 of this embodiment presents a relatively uniform correlated color temperature (CCT) at various angles.

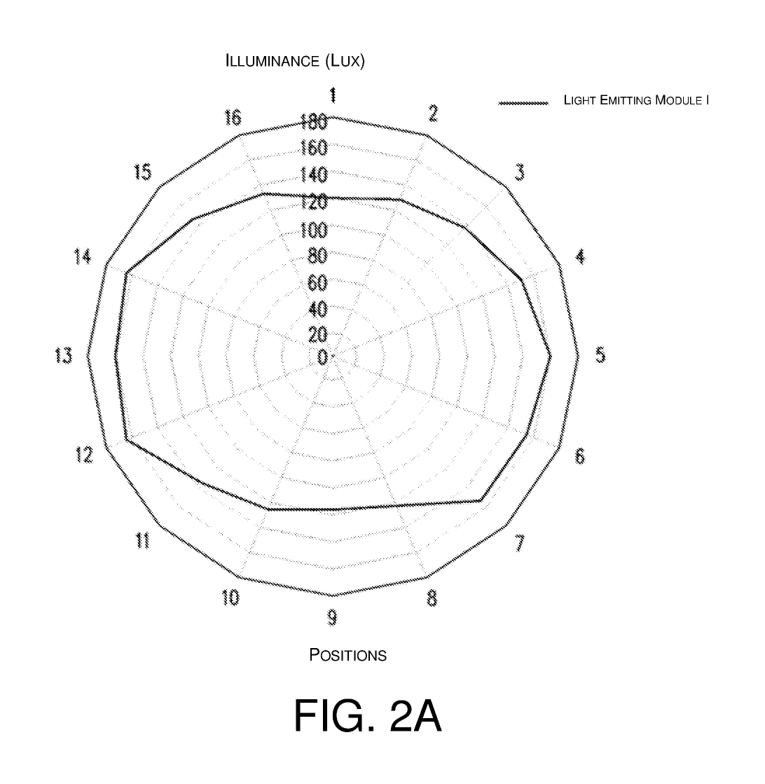

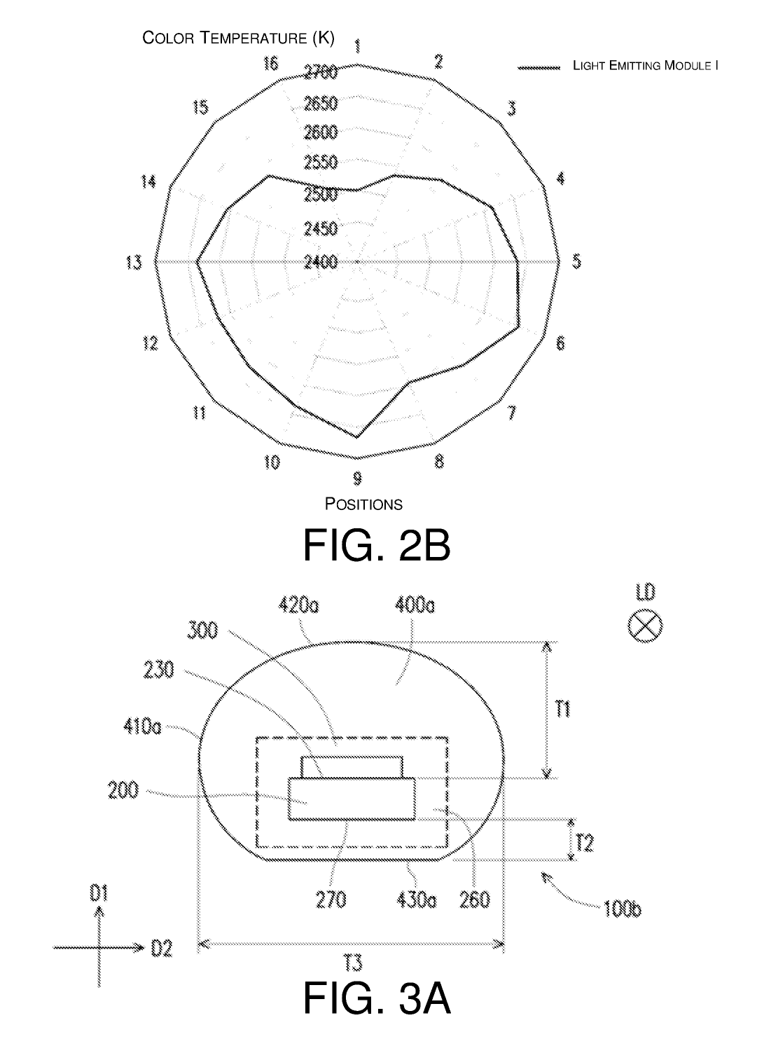

FIG. 2A is a graph of illuminance versus positions (angles) of the light emitting module shown in FIG. 1C. FIG. 2B is a graph of color temperature versus positions (angles) of the light emitting module shown in FIG. 1C. Please refer to FIG. 1A, FIG. 1C, FIG. 2A and FIG. 2B together. In FIG. 2A and FIG. 2B, the light emitting module I represents the light emitting module 100. Positions 1˜16 represents sixteen measured points that are equidistant from the light emitting module 100 in a plane that passes through a center point of the light emitting module 100 in the long side direction LD and that takes the long side direction LD as an axis. In particular, every two adjacent positions include an angle of 22.5° with respect to the light emitting module 100, so the arrangement of the measurement positions 1˜16 is equivalent to an arrangement in which one measurement point is disposed every 22.5° and the measurement is made for a whole cycle of 360°. Here, a direction from the light emitting module 100 to the position 1 coincides with the direction D1, while a direction from the light emitting module 100 to the position 9 is opposite to the direction D1.

In this embodiment, according to the illuminance graph of FIG. 2A, the light emitting module 100 can provide an effect of uniformly exiting light in various directions (at various angles) from the first surface 420 and the second surface 430 because the LEDs 300 are located within the fluorescent encapsulant 400. Therefore, the illuminance values of the light emitting module 100 measured at various angles (positions 1˜16) are very uniform, and the overall light distribution profile is very uniform. Among others, the illuminance value at the 180° angle (position 9) is very close to that at the 0° angle (position 1).

Also in this embodiment, according to the color temperature graph of FIG. 2B, because the upper encapsulant thickness T1 of the fluorescent encapsulant 400 is greater than the lower encapsulant thickness T2 in the light emitting module 100 of this embodiment, the path length of the light exiting from the first surface 420 and the path length of the light exiting from the second surface 430 become relatively close to each other. Therefore, there is no great difference between the color temperature values measured at the various angles (positions 1˜16). As compared with the light exiting from the first surface 420, still a large proportion of the light exiting from the second surface 430 is converted by the phosphor, so the color temperature value in the 180° (position 9) direction is slightly higher than that at the 0° (position 1) direction. However, generally speaking, the color temperature values of the light emitting module 100 measured at the various angles (positions 1˜16) mostly fall into the range of 2500K to 2650K.

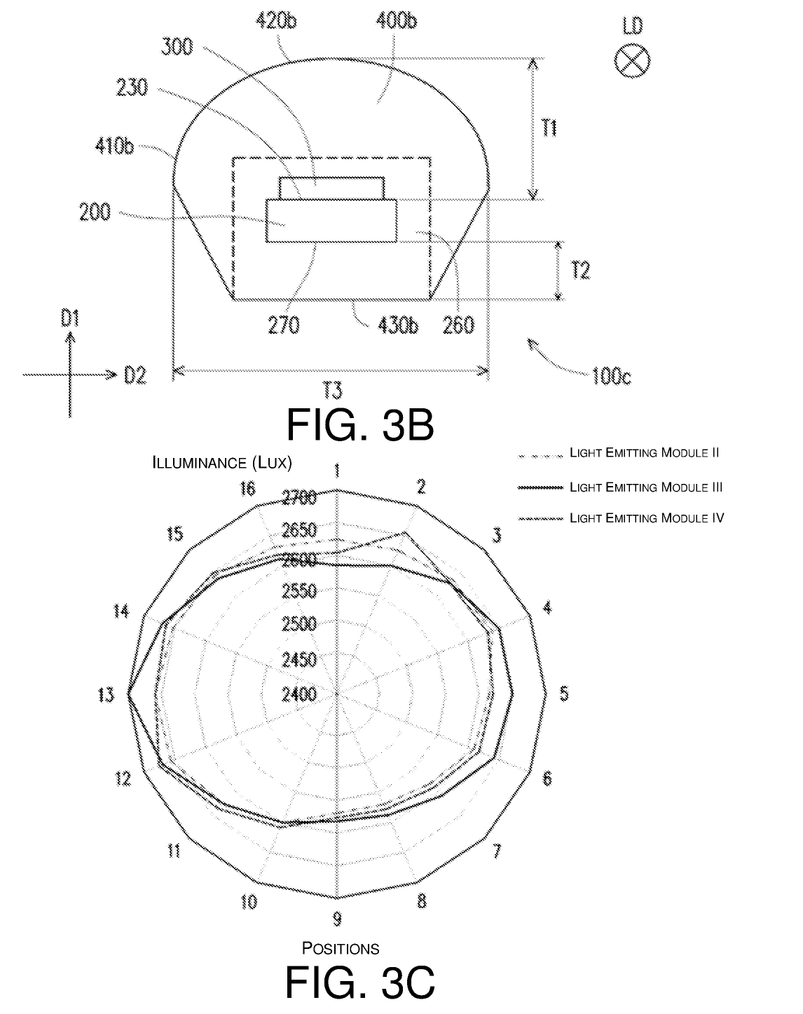

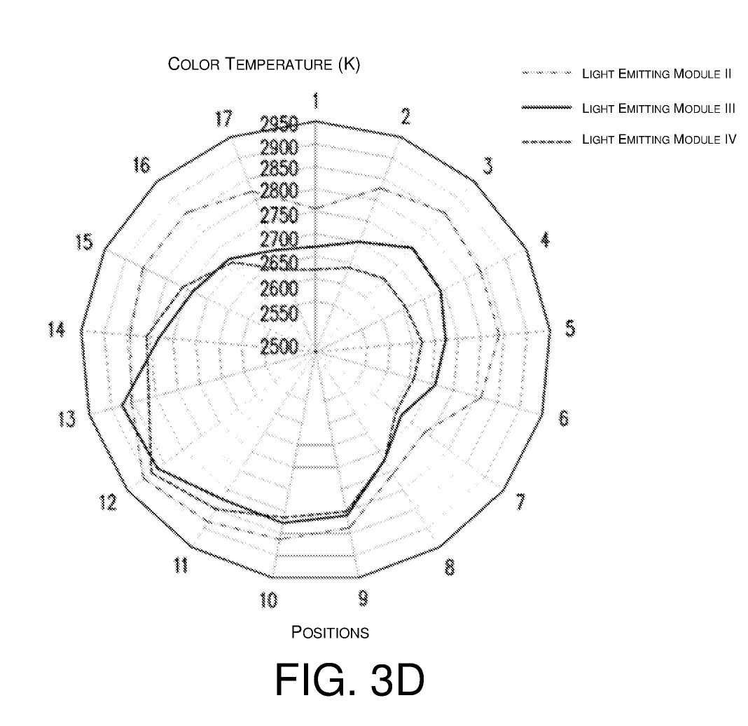

FIG. 3A is a schematic cross-sectional view of a light emitting module according to a further embodiment of the present invention. Referring to FIG. 3A, the light emitting module 100b in this embodiment is substantially identical to the light emitting module 100 of FIG. 1C, so for the similar members and related functions, reference may be made to the description of the light emitting module 100 and no further description will be made herein. The light emitting module 100b differs from the light emitting module 100 mainly in that, the first surface 420a of the fluorescent encapsulant 400a is a curved convex surface and the second surface 430a is a planar or approximately planar surface in the light emitting module 100b. In particular, at least a part of the backed encapsulant of the light emitting module 100b is removed (or the fluorescent encapsulant 400a at the second surface 430a side is formed to be relatively thin, or substantially no fluorescent encapsulant 400a is formed on the second surface 430a side, or substantially no fluorescent encapsulant 400a is formed on the back surface 270 side of the electrode substrate 200), and the upper encapsulant thickness T1, the lower encapsulant thickness T2 and the side encapsulant thickness T3 of the light emitting module 100b are appropriately adjusted. Also in this embodiment, it may be unnecessary to completely cover the insulative connecting portion 260 with the fluorescent encapsulant 400a, that is, it may be that a part of the insulative connecting portion 260 is located within the fluorescent encapsulant 400a and the rest of the insulative connecting portion 260 is exposed to the service environment of the light emitting module 100b.

FIG. 3B is a schematic cross-sectional view of a light emitting module according to yet a further embodiment of the present invention. Referring to FIG. 3B, the light emitting module 100c in this embodiment is substantially identical to the light emitting module 100b of FIG. 3A, so for the similar members and related functions, reference may be made to the description of the light emitting module 100b and no further description will be made herein. In particular, the first surface 420b of the fluorescent encapsulant 100c is a curved convex surface and the second surface 430b is a planar or approximately planar surface in the light emitting module 100c. Furthermore, not only at least a part of the backed encapsulant of the light emitting module 100c is removed (or the fluorescent encapsulant 400b at the second surface 430b side is formed to be relatively thin, or substantially no fluorescent encapsulant 400b is formed on the second surface 430b side, or substantially no fluorescent encapsulant 400b is formed on the back surface 270 side of the electrode substrate 200), but a part of the side encapsulant is also removed or formed directly into the side encapsulant form and thickness shown in the embodiment of FIG. 3B. Besides, the upper encapsulant thickness T1, the lower encapsulant thickness T2 and the side encapsulant thickness T3 of the light emitting module 100b are appropriately adjusted. In this embodiment, both the LEDs 300 and the insulative connecting portion 260 are located within the fluorescent encapsulant 400b.

FIG. 3C is a graph of illuminance versus positions (angles) of the light emitting module shown in FIG. 3A. FIG. 3D is a graph of color temperature versus positions (angles) of the light emitting module shown in FIG. 3A. Please refer to FIG. 3A, FIG. 3C and FIG. 3D together. In FIG. 3C and FIG. 3D, the light emitting module II represents the light emitting module 100b, in which the upper encapsulant thickness T1 of the fluorescent encapsulant 400a is 1.2 mm, the lower encapsulant thickness T2 is 0.3 mm and the side encapsulant thickness T3 is 1.55 mm. The light emitting module III represents the light emitting module 100b, in which the upper encapsulant thickness T1 of the fluorescent encapsulant 400a is 1.3 mm, the lower encapsulant thickness T2 is 0.3 mm and the side encapsulant thickness T3 is 1.55 mm. The light emitting module IV represents the light emitting module 100b, in which the upper encapsulant thickness T1 of the fluorescent encapsulant 400a is 1.3 mm, the lower encapsulant thickness T2 is 0.3 mm and the side encapsulant thickness T3 is 1.65 mm. Arrangement of the positions 1˜16 are just identical to that of FIG. 2A and FIG. 2B, and reference may be made to the description of the positions 1˜16 of FIG. 2A and FIG. 2B, so no further description will be made herein.

According to the illuminance graph of FIG. 3C, the light emitting module 300 can provide an effect of uniformly exiting light in various directions (at various angles) from the first surface 420a and the second surface 430a because the LEDs 300 are located within the fluorescent encapsulant 400a. Therefore, the illuminance values of the light emitting modules II, III and IV measured at various angles (positions 1˜16) are very uniform. In this embodiment, the overall light distribution profiles of the three light emitting modules are all very uniform.

According to the color temperature graph of FIG. 3D, because as compared with the light exiting from the first surface 420a, still a large proportion of the light exiting from the second surface 430a is converted by the phosphor, the color temperature values of the light emitting modules II, III and IV in the 180° (position 9) direction are slightly higher than those at the 0° (position 1) direction. Generally speaking, the color temperature values of the light emitting module II measured at the various angles (positions 1˜17) mostly fall into the range of 2750K to 2900K, the color temperature values of the light emitting module III measured at the various angles (positions 1˜17) mostly fall into the range of 2700K to 2900K, and the color temperature values of the light emitting module IV measured at the various angles (positions 1˜16) mostly fall into the range of 2650K to 2900K. In this embodiment, the color temperature uniformity of all the light emitting modules II, III and IV fall within the allowable range.

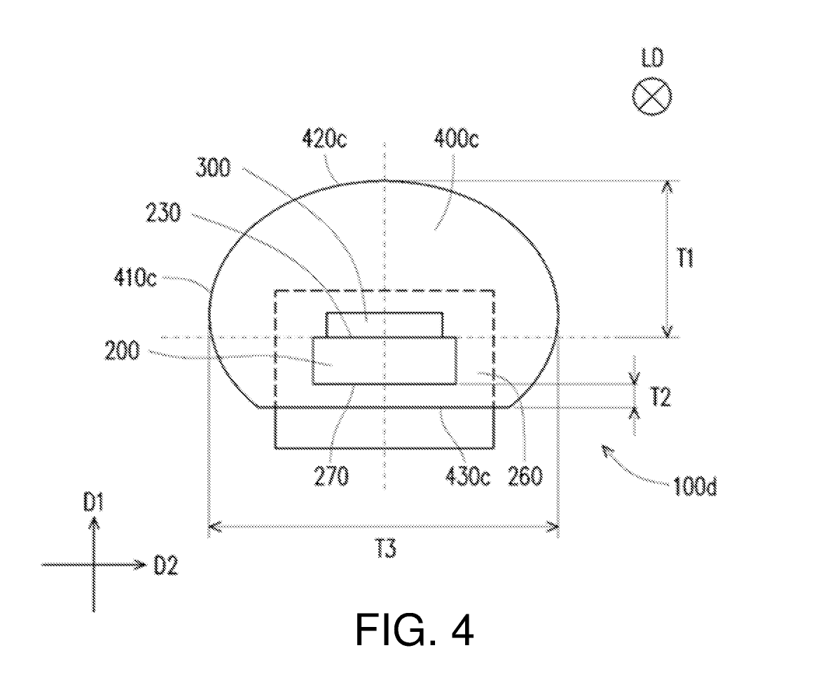

FIG. 4 is a schematic cross-sectional view of a light emitting module according to yet another embodiment of the present invention. Referring to FIG. 4, the light emitting module 100d in this embodiment is substantially identical to the light emitting module 100c of FIG. 3B, so for the similar members and related functions, reference may be made to the description of the light emitting module 100c and no further description will be made herein. In particular, the fluorescent encapsulant 400c is formed to be relatively thin on the second surface 430c side of the light emitting module 100d (or substantially no fluorescent encapsulant 400c is formed on the second surface 430c side, or substantially no fluorescent encapsulant 400c is formed on the back surface 270 side of the electrode substrate 200), so at least a part of the insulative connecting portion 260 is not coated by the fluorescent encapsulant 400c. Besides, in this embodiment, a ratio of the lower encapsulant thickness T2 to the upper encapsulant thickness T1 may be greater than 0 but no greater than 0.25.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A light emitting module, comprising:
an electrode substrate comprising a carrying surface, the electrode substrate further comprising a first joint portion and a second joint portion that are located at two opposite ends of the electrode substrate respectively, the first joint portion comprising a first through hole or a first notch; and
a plurality of light emitting diodes (LEDs) disposed on the carrying surface of the electrode substrate, wherein the LEDs are arranged along a long side direction of the electrode substrate and are electrically coupled to the electrode substrate.

2. The light emitting module of claim 1, wherein the electrode substrate comprises a first electrode board, a second electrode board and an electrically-insulative connecting portion configured to connect the first electrode board and the second electrode board, wherein the LEDs are disposed on the second electrode board, and wherein each of the LEDs has one end thereof electrically connected to the first electrode board and another end thereof electrically connected to the second electrode board.

3. The light emitting module of claim 1, further comprising a fluorescent encapsulant that covers the electrode substrate and the LEDs.

4. The light emitting module of claim 1, wherein the LEDs comprise one or more high-voltage (HV) LEDs, one or more direct-current (DC) LEDs, one or more alternating-current (AC) LEDs, or a combination thereof.

5. The light emitting module of claim 1, wherein the electrode substrate further comprises apertures for light transmission.

6. The light emitting module of claim 3, wherein the fluorescent encapsulant covers the electrode substrate and the LEDs in an encapsulant form in a surface direction orthogonal to the long side direction of the electrode substrate, and wherein the fluorescent encapsulant extends to cover the electrode substrate and the LEDs in the encapsulant form along the long side direction of the electrode substrate and encapsulates the LEDs therein.

7. The light emitting module of claim 3, wherein the fluorescent encapsulant has a first surface and a second surface that are opposite to each other, wherein the LEDs and the electrode substrate are located between the first surface and the second surface, wherein the carrying surface of the electrode substrate faces towards the first surface, wherein a maximum distance between the carrying surface and the first surface in a direction perpendicular to the carrying surface is an upper encapsulant thickness, wherein a maximum distance between a back surface of the electrode substrate that is opposite to the carrying surface and the second surface in the direction perpendicular to the carrying surface is a lower encapsulant thickness, and wherein the upper encapsulant thickness is greater than the lower encapsulant thickness.

8. The light emitting module of claim 7, wherein the first surface of the fluorescent encapsulant comprises a curved convex surface and the second surface of the fluorescent encapsulant comprises a curved convex surface.

9. The light emitting module of claim 7, wherein the first surface of the fluorescent encapsulant comprises a curved convex surface and the second surface of the fluorescent encapsulant comprises a planar surface.

10. The light emitting module of claim 1, wherein the second joint portion of the electrode substrate comprises a second through hole or a second notch.

11. A light emitting module, comprising:
an electrode substrate comprising a carrying surface;
a plurality of light emitting diodes (LEDs) disposed on the carrying surface of the electrode substrate, wherein the LEDs are arranged along a long side direction of the electrode substrate and electrically coupled to the electrode substrate; and
a fluorescent encapsulant covering the electrode substrate and the LEDs,
wherein the fluorescent encapsulant has a first surface and a second surface that are opposite to each other,
wherein the LEDs and the electrode substrate are located between the first surface and the second surface,
wherein the carrying surface faces towards the first surface,
wherein a maximum distance between the carrying surface and the first surface in a direction perpendicular to the carrying surface is an upper encapsulant thickness,
wherein a maximum distance between a back surface of the electrode substrate that is opposite to the carrying surface and the second surface in the direction perpendicular to the carrying surface is a lower encapsulant thickness, and
wherein the upper encapsulant thickness is greater than the lower encapsulant thickness.

12. The light emitting module of claim 11, wherein the fluorescent encapsulant covers the electrode substrate and the LEDs in an encapsulant form in a surface direction orthogonal to the long side direction of the electrode substrate, and wherein the fluorescent encapsulant extends to cover the electrode substrate and the LEDs in the encapsulant form along the long side direction of the electrode substrate and encapsulates the LEDs therein.

13. The light emitting module of claim 11, wherein the first surface of the fluorescent encapsulant comprises a curved convex surface and the second surface of the fluorescent encapsulant comprises a curved convex surface.

14. The light emitting module of claim 11, wherein the first surface of the fluorescent encapsulant comprises a curved convex surface and the second surface of the fluorescent encapsulant comprises a planar surface.

15. The light emitting module of claim 11, wherein the LEDs comprise one or more high-voltage (HV) LEDs, one or more direct-current (DC) LEDs, one or more alternating-current (AC) LEDs, or a combination thereof.

16. The light emitting module of claim 11, wherein the electrode substrate further comprises apertures for light transmission.
